(19) United States
(12) Patent Application Publication
(10) Pub. No.: US 2024/0421815 A1
(43) Pub. Date: Dec. 19, 2024

(54) SWITCHING MODULE

(71) Applicant: SANSHA ELECTRIC MANUFACTURING CO., LTD., Osaka (JP)

(72) Inventors: Tsukasa YASUDA, Osaka-shi (JP); Masashi FUKAI, Osaka-shi (JP)

(21) Appl. No.: 18/740,871

(22) Filed: Jun. 12, 2024

(30) Foreign Application Priority Data
Jun. 15, 2023 (JP) 2023-098383

(51) Int. Cl. H03K 17/56

(52) U.S. Cl. CPC H03K 17/56

(57) ABSTRACT

A switching module of the present disclosure includes: a plurality of switching elements each including a first electrode, a second electrode, and a control electrode; a first electrode wiring; a second electrode wiring; a control electrode wiring; and a Kelvin wiring including a common Kelvin wiring and individual Kelvin wirings electrically connecting the common Kelvin wiring to the second electrode of each of the plurality of switching elements. A Kelvin wiring predetermined portion is at least one of the individual Kelvin wirings corresponding to at least one of the plurality of switching elements and has a resistance value of 1 mΩ or more, or the Kelvin wiring predetermined portion is at least a part of the common Kelvin wiring and has a resistance value of 3 mΩ or more.

### BACKGROUND OF THE INVENTION

This application claims the benefit of foreign priority to Japanese Patent Application No. JP2023-098383, filed Jun. 15, 2023, which is incorporated by reference in its entirety.

### FIELD OF THE INVENTION

The present invention relates to a switching module.

### DESCRIPTION OF RELATED ART

It is conventionally known that a wiring Kelvin-connected to a switching element is provided and a gate voltage is applied between the Kelvin-connected wiring and a gate of the switching element.

JP 2019-220563 A (particularly see paragraphs [0116] to [0117] and FIG. 22) describes that in a power module including a switching element, a current flowing through a Kelvin-connected wiring and a current flowing between main terminals of the switching element are divided from each other.

### SUMMARY OF THE INVENTION

### Technical Problem

Wide bandgap semiconductors such as SiC and GaN are recently adopted as switching elements, resulting in speed up of operations of switching elements. Furthermore, the current capacity of a switching element is increased. Meanwhile, in manufacture of a wide bandgap semiconductor, a crystal defect in the substrate decreases the yield to limit expansion of the size of the chip incorporating the switching element. Therefore, in the case of applying a switching element with a wide bandgap semiconductor to a high current capacity application, a plurality of switching elements connected in parallel to each other are used instead of one switching element in a low current capacity application.

However, in a case where each of the plurality of switching elements connected in parallel to each other has a Kelvin-connected wiring, a deviation in timing of turn-on or turn-off (hereinafter, referred to as switching) between the switching elements may exceed the allowable limit.

The present invention has been made to solve such a problem, and an object of the present invention is to provide a switching module that includes a plurality of switching elements each having a Kelvin-connected wiring and connected in parallel to each other, and is capable of reducing an excess of a deviation in switching timing between the switching elements over an allowable limit.

### Solution to Problem

### Findings on which the Present Invention is Based on

The present inventors have extensively studied for solving the above-described problem, and in the study, have found a phenomenon that at the time of high-speed operation of a switching module in which each of a plurality of switching elements connected in parallel to each other has a Kelvin-connected wiring, the main currents of the plurality of switching elements partially diverge into the Kelvin-connected wirings according to the layout conditions of the switching elements and the wirings, and that switching noise due to parasitic impedance of the wirings of the switching module is superimposed on the diverging currents. This phenomenon was unexpected for the present inventors. The present inventors investigated the cause by simulation and the like described below, and concluded that the cause of occurrence of this phenomenon was as follows.

In the case of using a plurality of switching elements connected in parallel to each other instead of one switching element, the Kelvin-connected wirings (hereinafter, referred to as Kelvin sense wirings) of the plurality of switching elements may be linked by a common Kelvin wiring. Meanwhile, a parasitic resistance exists in a wiring that supplies a main current to the plurality of switching elements connected in parallel to each other, and the parasitic resistance generally causes a potential difference between the sources of the plurality of switching elements. In this state, if the common Kelvin wiring links the sources of the plurality of switching elements, a short-circuit current flows so that the sources of the plurality of switching elements have a potential difference corresponding to the resistance values of the Kelvin sense wirings and the common Kelvin wiring. Specifically, the short-circuit current flows out from a Kelvin sense wiring of a switching element having a high source potential, flows backward through a Kelvin sense wiring of a switching element having a low source potential, and merges into the main current of the switching element having a low source potential. As a result, in the switching element having a high source potential, the main current decreases by the amount of the short-circuit current that has flowed out, and the source potential decreases. In the switching element having a low source potential, the main current increases by the amount of the merged short-circuit current, and the source potential increases. The magnitude of the short-circuit current is determined to balance the decrease in the potential difference between the sources of both the switching elements with the decrease in the short-circuit current. This short-circuit current is the “diverging current”.

Then, the present inventors have concluded that the “diverging current” of the main current fluctuates due to switching noise, and that if the “diverging current” exceeds the limit, the above-described problem occurs.

As a result of various studies, it has been found that an increase in the resistance value of the Kelvin sense wiring or the common Kelvin wiring can reduce diverging of a part of the main currents of the plurality of switching elements into the Kelvin sense wirings, and can reduce switching noise superimposed on the diverging current. In this case, it is estimated that the high resistance value of the Kelvin sense wiring or the common Kelvin wiring suppresses the diverging current itself and functions as a damper to suppress fluctuation of the diverging current.

The present invention has been made on the basis of such findings, and in order to achieve the above-described object, a switching module according to an aspect of the present disclosure is a switching module comprising: a plurality of switching elements connected in parallel, the plurality of switching elements each including a first electrode, a second electrode, and a control electrode that controls a main current flowing between the first electrode and the second electrode by a potential difference with respect to the second electrode; a first electrode wiring electrically connected to the first electrode of each of the plurality of switching elements; a second electrode wiring electrically connected to the second electrode of each of the plurality of switching elements; a control electrode wiring electrically connected to the control electrode of each of the plurality of switching elements; and a Kelvin wiring including a common Kelvin wiring and individual Kelvin wirings electrically connecting the common Kelvin wiring to the second electrode of each of the plurality of switching elements, wherein the Kelvin wiring has a Kelvin wiring predetermined portion that is at least a part of the Kelvin wiring, and the Kelvin wiring predetermined portion is at least one of the individual Kelvin wirings corresponding to at least one of the plurality of switching elements and has a resistance value of 1 mΩ or more, or the Kelvin wiring predetermined portion is at least a part of the common Kelvin wiring and has a resistance value of 3 mΩ or more.

### Advantageous Effects of Invention

The present invention has an effect of providing a switching module that includes a plurality of switching elements each having a Kelvin-connected wiring and connected in parallel to each other, and is capable of reducing an excess of a deviation in switching timing between the switching elements over an allowable limit.

### BRIEF DESCRIPTION OF THE DRAWINGS

FIG. 1A is a circuit diagram showing an outline of a first configuration example of a switching module according to an embodiment of the present disclosure;

FIG. 1B is a circuit diagram showing an outline of a second configuration example of a switching module according to an embodiment of the present disclosure;

FIG. 2A is a perspective view showing an appearance of a discrete component incorporating a single switching element;

FIG. 2B is a circuit diagram showing an equivalent circuit of the discrete component of FIG. 2A;

FIG. 3 is a circuit diagram showing an equivalent circuit of one switching element of a module incorporating a plurality of switching elements connected in parallel to each other and internal wirings related to the switching element;

FIG. 4 is a circuit diagram showing an example of a configuration of a switching module that embodies the first configuration example of the switching module of FIG. 1A using the discrete component incorporating a single switching element of FIGS. 2A and 2B;

FIG. 5 is a circuit diagram showing an example of a configuration of a switching module that embodies the first configuration example of the switching module of FIG. 1A using the module incorporating a plurality of switching elements connected in parallel to each other of FIG. 3;

FIG. 6 is a circuit diagram showing an equivalent circuit of a switching module in a first simulation;

FIG. 7 is a graph showing current values of individual Kelvin wirings in a simulation using the equivalent circuit of FIG. 6;

FIG. 8 is a circuit diagram showing an equivalent circuit of a switching module in a second simulation;

FIG. 9 is a graph showing current values of individual Kelvin wirings in a simulation using the equivalent circuit of FIG. 8; and

FIG. 10 is a view illustrating an appearance of a state of mounting of a full-bridge current resonance circuit in which the switching module of FIG. 1A is used as a high-side switching module.

### DETAILED DESCRIPTION OF EMBODIMENTS

A switching module according to an aspect of the present disclosure is a switching module including: a plurality of switching elements connected in parallel and each including a first electrode, a second electrode, and a control electrode that controls a main current flowing between the first electrode and the second electrode by a potential difference with respect to the second electrode; a first electrode wiring electrically connected to the first electrode of each of the plurality of switching elements; a second electrode wiring electrically connected to the second electrode of each of the plurality of switching elements; a control electrode wiring electrically connected to the control electrode of each of the plurality of switching elements; and a Kelvin wiring including a common Kelvin wiring and individual Kelvin wirings electrically connecting the common Kelvin wiring to the second electrode of each of the plurality of switching elements, wherein the Kelvin wiring has a Kelvin wiring predetermined portion that is at least a part of the Kelvin wiring, and the Kelvin wiring predetermined portion is at least one of the individual Kelvin wirings corresponding to at least one of the plurality of switching elements and has a resistance value of 1 mΩ or more, or the Kelvin wiring predetermined portion is at least a part of the common Kelvin wiring and has a resistance value of 3 mΩ or more. Here, the “common Kelvin wiring” is a concept including a Kelvin wiring terminal.

According to this configuration, the Kelvin wiring predetermined portion is at least one of the individual Kelvin wirings corresponding to at least one of the plurality of switching elements and has a resistance value of 1 mΩ or more, or the Kelvin wiring predetermined portion is at least a part of the common Kelvin wiring and has a resistance value of 3 mΩ or more. Therefore, a part of the main current is less likely to diverge into the individual Kelvin wiring and the common Kelvin wiring in the on period of the switching element, and switching noise (hereinafter, sometimes simply referred to as “superimposed switching noise”) is less likely to be caused by the parasitic impedance of various wirings superimposed on the diverging current (hereinafter, sometimes simply referred to as “diverging current”), than in a case where the Kelvin wiring has only the parasitic resistance. As a result, it is possible to reduce an excess of a deviation in switching timing between the switching elements over an allowable limit.

The plurality of switching elements may be a number n (n is an integer of 2 or more) of switching elements, and the Kelvin wiring predetermined portion may be the individual Kelvin wirings corresponding to a number n or n−1 of the switching elements.

According to this configuration, in a case where the Kelvin wiring predetermined portion is the individual Kelvin wirings corresponding to a number n of the switching elements, the “diverging current” and the “superimposition of switching noise” are clearly reduced because the individual Kelvin wirings corresponding to all of the switching elements have a resistance value of 1 mΩ or more. In a case where the Kelvin wiring predetermined portion is the individual Kelvin wirings corresponding to a number n−1 of the switching elements, the current value of the “diverging current” does not significantly depend on whether the individual Kelvin wiring corresponding to the remaining one switching element is the Kelvin wiring predetermined portion. Therefore, the “diverging current” and the “superimposition of switching noise” are clearly reduced in the almost same manner as in a case where the Kelvin wiring predetermined portion is the individual Kelvin wirings corresponding to a number n of the switching elements.

The Kelvin wiring predetermined portion may have a resistance value of 4 mΩ or more. According to this configuration, the “diverging current” and the “superimposition of switching noise” are effectively reduced.

The Kelvin wiring predetermined portion may have a resistance value of 10 mΩ or more. According to this configuration, the “diverging current” and the “superimposition of switching noise” are excellently reduced.

The Kelvin wiring predetermined portion may have a resistance value of 100 mΩ or more. According to this configuration, the “diverging current” and the “superimposition of switching noise” are remarkably reduced.

The common Kelvin wiring may extend so as to have both ends, the individual Kelvin wirings corresponding to the plurality of switching elements may be electrically connected to the common Kelvin wiring at an interval, and the Kelvin wiring predetermined portion may be a portion between a pair of points, in the common Kelvin wiring, to which a pair of the individual Kelvin wirings of a pair of the switching elements adjacent to each other are connected while the portion corresponds to all of the switching elements. Hereinafter, the “portion between a pair of points, in the common Kelvin wiring, to which a pair of the individual Kelvin wirings of a pair of the switching elements adjacent to each other are connected” is referred to as the “common Kelvin wiring specific portion”.

According to this configuration, the “diverging current” and the “superimposition of switching noise” are clearly reduced because the Kelvin wiring predetermined portion is the common Kelvin wiring specific portion corresponding to all of the switching elements and has a resistance value of 3 mΩ or more.

The Kelvin wiring predetermined portion may have a resistance value of 12 mΩ or more.

According to this configuration, the “diverging current” and the “superimposition of switching noise” are excellently reduced.

The Kelvin wiring predetermined portion may have a resistance value of 30 mΩ or more.

According to this configuration, the “diverging current” and the “superimposition of switching noise” are very excellently reduced.

The Kelvin wiring predetermined portion may have a resistance value of 300 m52 or more. According to this configuration, the “diverging current” and the “superimposition of switching noise” are very remarkably reduced.

The sum of the resistance value of the Kelvin wiring predetermined portion and the resistance value of a control electrode resistor disposed on the control electrode wiring of the switching elements corresponding to the Kelvin wiring predetermined portion may be the recommended gate resistance value of the switching elements.

According to this configuration, the resistance value of the substantial control electrode resistor of the switching elements corresponding to the Kelvin wiring predetermined portion is equal to the recommended gate resistance value of the switching elements, and therefore the switching elements can be suitably operated.

The Kelvin wiring predetermined portion may have a resistance value of 1 kΩ or less.

According to this configuration, the resistance value of the substantial control electrode resistor of the switching elements corresponding to the Kelvin wiring predetermined portion can be equal to the recommended gate resistance value of the switching elements by selecting an appropriate resistance value of 1 kΩ or less as the resistance value of the Kelvin wiring predetermined portion, and therefore the switching elements can be suitably operated.

The control electrode wiring may include a common control electrode wiring having one end connected to a control wiring terminal and the other end terminated, and individual control electrode wirings electrically connecting the common control electrode wiring to the control electrode of each of the plurality of switching elements.

According to this configuration, the plurality of switching elements can be operated as one switching element by a common control electrode drive signal.

The control electrode wiring may include a plurality of single control electrode wirings connected to a plurality of control wiring terminals, respectively, at one end and electrically connected to the control electrode of each of the plurality of switching elements at the other end.

According to this configuration, the plurality of switching elements can be operated so as to be different from each other by inputting a plurality of different control electrode drive signals to the plurality of control wiring terminals.

The switching elements may be an insulated gate bipolar transistor (IGBT), a field effect transistor, or a bipolar transistor.

According to this configuration, the switching module can be easily configured.

Hereinafter, specific embodiments of the present disclosure will be described with reference to the drawings. In the following description, the same or corresponding elements are denoted by the same reference signs throughout all the drawings, and redundant description of the elements will be omitted. The drawings described below are for describing the present disclosure, and therefore in the drawings, an element unrelated to the present disclosure may be omitted, a dimension may be inaccurate for exaggeration or the like, simplification may be performed, or the forms of elements corresponding to each other may be inconsistent in a plurality of drawings. The present disclosure is not limited to the following embodiments.

### EMBODIMENTS

First, an outline of a switching module 100 according to an embodiment of the present disclosure will be described.

### Outline

The switching module 100 has a first configuration example and a second configuration example.

### {Configuration of First Configuration Example}

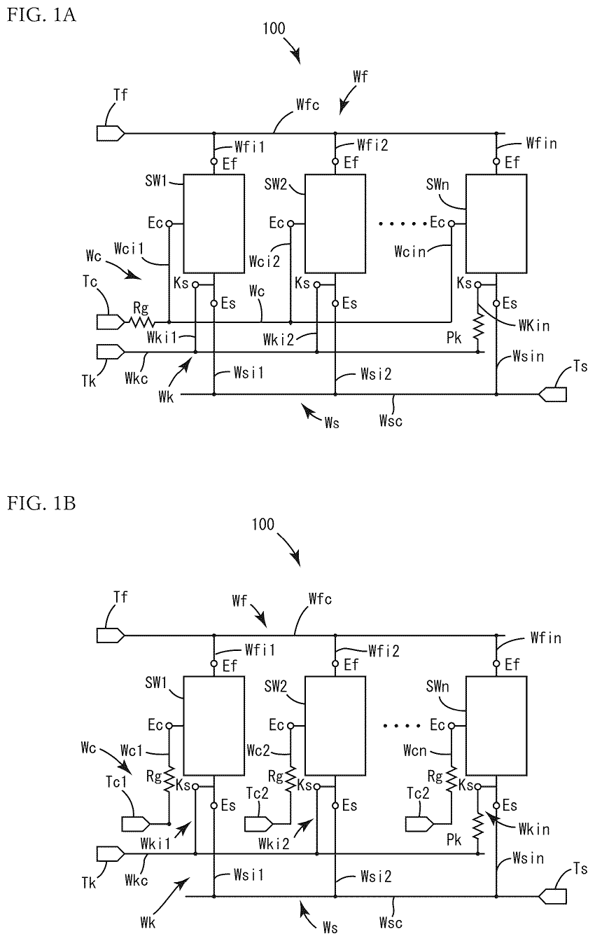

FIG. 1A is a circuit diagram showing an outline of the first configuration example of the switching module 100 according to an embodiment of the present disclosure. The first configuration example is configured to operate a plurality of switching elements SW1 to SWn as one switching element. In the first configuration example, the plurality of switching elements SW1 to SWn are designed to be turned on at predetermined identical on-timing and to be turned off at predetermined identical off-timing, and allowable limits are determined for the deviation from the on-timing and the deviation from the off-timing. The first configuration example is applied to, for example, a switching module having a high current capacity.

Referring to FIG. 1A, the switching module 100 of the first configuration example includes the plurality of switching elements SW1 to SWn, a first electrode wiring Wf, a control electrode wiring Wc, a second electrode wiring Ws, and a Kelvin wiring Wk. The plurality of switching elements SW1 to SWn are connected in parallel to each other between the first electrode wiring Wf and the second electrode wiring Ws. Hereinafter, this configuration will be described in detail.

### <Switching Elements SW1 to SWn>

Each of the switching elements SW1 to SWn includes a first electrode Ef, a second electrode Es, and a control electrode Ec that controls a main current flowing between the first electrode Ef and the second electrode Es by a potential difference with respect to the second electrode Es. That is, each of the switching elements SW1 to SWn is a transistor. As each of the switching elements SW1 to SWn, for example, a field effect transistor (FET), an insulated gate bipolar transistor (IGBT), a bipolar transistor, or another transistor can be used. Examples of the FET include a metal oxide semiconductor field effect transistor (MOSFET), a metal semiconductor field effect transistor (MESFET), and a Junction field effect transistor (JFET). In the FET, the first electrode Ef, the second electrode Es, and the control electrode Ec are a drain, a source, and a gate, respectively. In the IGBT, the first electrode Ef, the second electrode Es, and the control electrode Ec are a collector, an emitter, and a gate, respectively. In the bipolar transistor, the first electrode Ef, the second electrode Es, and the control electrode Ec are a collector, an emitter, and a base, respectively.

### <First Electrode Wiring Wf>

The first electrode wiring Wf is electrically connected to the first electrode Ef of each of the plurality of switching elements SW1 to SWn. An aspect of the connection between the first electrode wiring Wf and the first electrode Ef of each of the plurality of switching elements SW1 to SWn is not particularly limited. For example, the first electrode wiring Wf includes a common first electrode wiring Wfc and individual first electrode wirings Wfi1 to Wfin. The first electrode wiring Wf has one end formed on a first wiring terminal Tf and the other end terminated. The first wiring terminal Tf is connected to a high potential side terminal of a power supply. The common first electrode wiring Wfc is connected to the first electrodes Ef of the plurality of switching elements SW1 to SWn by the individual first electrode wirings Wfi1 to Wfin. The material of the first electrode wiring Wf may be any conductive material. For example, copper is used as the material of the first electrode wiring Wf.

### <Second Electrode Wiring Ws>

The second electrode wiring Ws is electrically connected to the second electrode Es of each of the plurality of switching elements SW1 to SWn. Specifically, the second electrode wiring Ws includes a common second electrode wiring Wsc and individual second electrode wirings Wsi1 to Wsin. The common second electrode wiring Wsc has one end formed on a second wiring terminal Ts and the other end terminated. The second wiring terminal Ts is connected to a negative terminal of the power supply. The common second electrode wiring Wsc is connected to the second electrodes Es of the plurality of switching elements SW1 to SWn by the individual second electrode wirings Wsi1 to Wsin. An aspect of the connection between the plurality of individual second electrode wirings Wsi1 to Wsin corresponding to the plurality of switching elements SW1 to SWn respectively and the common second electrode wiring Wsc is not particularly limited. For example, the plurality of individual second electrode wirings Wsi1 to Wsin corresponding to the plurality of switching elements SW1 to SWn are connected to the common second electrode wiring Wsc at an interval. The material of the second electrode wiring Ws may be any conductive material. For example, copper is used as the material of the second electrode wiring Ws.

### <Control Electrode Wiring Wc>

The control electrode wiring Wc is electrically connected to the control electrode Ec of each of the plurality of switching elements SW1 to SWn. In the first configuration example, the control electrode wiring Wc includes a common control electrode wiring Wcc and individual control electrode wirings Wci1 to Wcin. The common control electrode wiring Wcc has one end formed on a control wiring terminal Tc and the other end terminated. The control wiring terminal Tc is connected to a high potential side terminal of a control electrode drive circuit. The common control electrode wiring Wcc is connected to the control electrodes Ec of the plurality of switching elements SW1 to SWn by the individual control electrode wirings Weil to Wcin. A gate resistor Rg is disposed on the common control electrode wiring Wcc between the individual control electrode wiring Weil that is the closest to the control wiring terminal Tc and connected to the common control electrode wiring Wcc and the control wiring terminal Tc. The material of the second electrode wiring Ws may be any conductive material.

### <Kelvin Wiring Wk>

The Kelvin wiring Wk is electrically connected to the second electrode Es of each of the plurality of switching elements SW1 to SWn so as to include a Kelvin sense wiring of each of the plurality of switching elements SW1 to SWn. Specifically, the Kelvin wiring Wk includes a common Kelvin wiring Wkc and individual Kelvin wirings Wki1 to Wkin. The common Kelvin wiring Wkc has one end formed on a Kelvin wiring terminal Tk and the other end terminated. The Kelvin wiring terminal Tk is connected to a low potential side terminal of the control electrode drive circuit. The common Kelvin wiring Wkc is connected to the second electrodes Es of the plurality of switching elements SW1 to SWn by the individual Kelvin wirings Wki1 to Wkin. The individual Kelvin wirings Wki1 to Wkin include the Kelvin sense wirings of the corresponding switching elements SW1 to SWn, respectively. Portions in the individual Kelvin wirings Wki1 to Wkin other than the Kelvin sense wirings connect terminals Ks of the Kelvin sense wirings to the common Kelvin wiring Wkc.

An aspect of the connection between the plurality of individual Kelvin wirings Wki1 to Wkin corresponding to the plurality of switching elements SW1 to SWn respectively and the common Kelvin wiring Wkc is not particularly limited. For example, the plurality of individual Kelvin wirings Wki1 to Wkin corresponding to the plurality of switching elements SW1 to SWn are connected to the common Kelvin wiring Wkc at an interval. Furthermore, for example, the entire common Kelvin wiring Wkc may be formed in the Kelvin wiring terminal Tk, and the individual Kelvin wirings Wki1 to Wkin may be connected to the Kelvin wiring terminal Tk.

The material of a portion in the Kelvin wiring Wk other than a Kelvin wiring predetermined portion Pk described below may be any conductive material, and for example, copper is used as the material. The Kelvin wiring predetermined portion Pk will be described in detail below.

### Technical Feature

The Kelvin wiring predetermined portion Pk, which is at least a part of the Kelvin wiring Wk including the common Kelvin wiring Wkc and all the individual Kelvin wirings Wki1 to Wkin, is at least one of the individual Kelvin wirings Wki1 to Wkin corresponding to at least one of the plurality of switching elements SW1 to SWn and has a resistance value of 1 mΩ or more, or the Kelvin wiring predetermined portion Pk is at least a part of the common Kelvin wiring Wkc and has a resistance value of 3 mΩ or more. The technical significance of this technical feature is as follows.

### Technical Significance

The technical significance of the above technical feature will be described separately for “the lower limit of the resistance value of the Kelvin wiring predetermined portion Pk”, “the position of the Kelvin wiring predetermined portion Pk”, and “the upper limit of the resistance value of the Kelvin wiring predetermined portion Pk”.

### {Lower Limit of Resistance Value of Kelvin Wiring Predetermined Portion Pk}

First, the lower limit of the resistance value of the Kelvin wiring predetermined portion Pk will be described.

A problem to be solved in the present invention is that in a case where a plurality of switching elements connected in parallel to each other each have a Kelvin-connected wiring, a deviation in timing of switching between the switching elements may exceed the allowable limit. This problem is caused if a part of a main current of the plurality of switching elements diverges into the Kelvin sense wiring and the diverging current fluctuates due to switching noise caused by parasitic impedances of various wirings.

Therefore, to deal with this problem, the resistance value of the Kelvin wiring predetermined portion Pk is set higher than the resistance value of the parasitic resistance of the Kelvin wiring predetermined portion Pk. As a result, the diverging current of the main current into the Kelvin wiring Wk is reduced, and the high resistance of the Kelvin wiring predetermined portion Pk functions as a damper to reduce the switching noise. Therefore, in this method, the resistance value of the Kelvin wiring predetermined portion Pk is preferably as large as possible, but it is obvious that the diverging current of the main current into the Kelvin wiring Wk and the switching noise superimposed on the diverging current cannot be completely eliminated. Meanwhile, the Kelvin sense wiring also has a parasitic resistance, and it is obvious that this parasitic resistance also suppresses the diverging current of the main current into the Kelvin sense wiring (“diverging current”) and the switching noise superimposed on the diverging current (“superimposed switching noise”). However, due to the increase in the speed of the operation of the switching element and the increase in the current capacity of the switching element, the parasitic resistance cannot sufficiently suppress the “diverging current” and the “superimposed switching noise”, and thus the above problem occurs. Therefore, it is obvious that if the resistance value of at least a part of the Kelvin wiring Wk is set higher than the parasitic resistance of the Kelvin wiring, the “diverging current” and the “superimposed switching noise” can be reduced. Therefore, in the present invention, the resistance value of the Kelvin wiring predetermined portion Pk is to be larger than the resistance value of the parasitic resistance of the Kelvin wiring predetermined portion Pk.

However, the parasitic resistance of a general Kelvin sense wiring cannot be clearly specified, and therefore the present inventors performed two simulations described below in order to clearly distinguish the present invention from the prior art. In the first simulation, the Kelvin wiring predetermined portion Pk was disposed in the individual Kelvin wirings Wki1 to Wkin. In the second simulation, the Kelvin wiring predetermined portion Pk was disposed in a common Kelvin wiring specific portion (portions, in the common Kelvin wiring Wkc, between each pair of points to which a pair among the individual Kelvin wirings Wki1 to Wkin corresponding a pair of adjacent switching elements among the switching elements SW1 to SWn were connected, respectively) of the common Kelvin wiring Wkc.

As a result of the first simulation, the following was confirmed.

As the resistance values of the individual Kelvin wirings Wki1 to Wkin including the Kelvin sense wirings increase, the fluctuation in the current of the individual Kelvin wirings Wki1 to Wkin monotonously decrease. The fact that the fluctuation in the current of the individual Kelvin wirings Wki1 to Wkin decrease means that the “diverging current” and the “superimposed switching noise” are reduced.

In a case where the resistance values of the individual Kelvin wirings Wki1 to Wkin are the resistance values (assumed to be 100μΩ) of the parasitic resistances of the individual Kelvin wirings Wki1 to Wkin (hereinafter, sometimes simply referred to as “parasitic resistances”), the degrees of the “diverging current” and the “superimposition of switching noise” are at a certain level. Meanwhile, in a case where the resistance values of the individual Kelvin wirings Wki1 to Wkin are 10 times (1 mΩ) the resistance value of the parasitic resistance, the “diverging current” and the “superimposition of switching noise” are clearly reduced as compared with the case where the resistance values of the individual Kelvin wirings Wki1 to Wkin are the resistance value of the parasitic resistance (100μΩ). However, in this simulation, it is presupposed that the Kelvin wiring predetermined portion Pk is provided in the individual Kelvin wirings Wki1 to Wkin of all the switching elements SW1 to SWn, and therefore, for example, in a case where the Kelvin wiring predetermined portion Pk is provided only in the individual Kelvin wiring of one of the plurality of switching elements SW1 to SWn, the effect is reduced. However, in this case, the resistance value of the entire Kelvin wiring Wk is certainly increased, and therefore the “diverging current” and the “superimposition of switching noise” are certainly reduced.

In a case where the resistance values of the individual Kelvin wirings Wki1 to Wkin are 40 times (4 mΩ) the resistance value of the parasitic resistance, the “diverging current” and the “superimposition of switching noise” are effectively reduced. In a case where the resistance values of the individual Kelvin wirings Wki1 to Wkin are 100 times (10 mΩ) the resistance value of the parasitic resistance, the “diverging current” and the “superimposition of switching noise” are excellently reduced. In a case where the resistance values of the individual Kelvin wirings Wki1 to Wkin are 1000 times (100 mΩ) the resistance value of the parasitic resistance, the “diverging current” and the “superimposition of switching noise” are remarkably reduced.

As a result of the second simulation, the following was confirmed.

In a case where the resistance value of the common Kelvin wiring specific portion is the resistance value (assumed to be 300μΩ) of the parasitic resistance, the magnitudes of the “diverging current” and the “superimposition of switching noise” are at a certain level. Meanwhile, in a case where the resistance value of the common Kelvin wiring specific portion is 10 times (3 mΩ) the resistance value of the parasitic resistance, the “diverging current” and the “superimposition of switching noise” are clearly smaller than those in the case where the resistance value of the common Kelvin wiring specific portion is the resistance value (300μΩ) of the parasitic resistance. However, in this simulation, it is presupposed that the Kelvin wiring predetermined portion Pk is provided in the common Kelvin wiring specific portion corresponding to all the switching elements SW1 to SWn, and therefore, for example, in a case where the Kelvin wiring predetermined portion Pk is provided only in the common Kelvin wiring specific portion of one pair of switching elements among the plurality of switching elements SW1 to SWn, the effect is reduced. However, in this case, the resistance value of the entire Kelvin wiring Wk is certainly increased, and therefore the “diverging current” and the “superimposition of switching noise” are certainly reduced.

In a case where the resistance value of the common Kelvin wiring specific portion is 40 times (12 mΩ) the resistance value of the parasitic resistance, the “diverging current” and the “superimposition of switching noise” are estimated to be excellently reduced. In a case where the resistance value of the common Kelvin wiring specific portion is 100 times (30 mΩ) the resistance value of the parasitic resistance, the “diverging current” and the “superimposition of switching noise” are estimated to be very excellently reduced. In a case where the resistance value of the common Kelvin wiring specific portion is 1000 times (300 mΩ) the resistance value of the parasitic resistance, the “diverging current” and the “superimposition of switching noise” are very remarkably reduced.

Meanwhile, as far as the present inventors know, the parasitic resistances of the Kelvin sense wiring and the common Kelvin wiring specific portion are about 100μΩ and 300μΩ, respectively. Here, what is to be particularly noted is that it has been generally considered that a Kelvin-connected wiring preferably has a resistance value as low as possible because the voltage of a control electrode drive signal is applied between the Kelvin-connected wiring and the control electrode wiring.

Therefore, in a case where the Kelvin wiring predetermined portion Pk is at least one of the individual Kelvin wirings Wki1 to Wkin corresponding to at least one of the plurality of switching elements SW1 to SWn, the present inventors have specified the resistance value of 1 mΩ as the lower limit of the range of the resistance value of the Kelvin wiring predetermined portion Pk in the present invention, and in a case where the Kelvin wiring predetermined portion Pk is at least a part of the common Kelvin wiring Wkc, the present inventors have specified the resistance value of 3 mΩ as the lower limit of the range of the resistance value of the Kelvin wiring predetermined portion Pk in the present invention. As a result, the present invention is clearly distinguished from the prior art. Furthermore, according to the present invention, the “diverging current” and the “superimposed switching noise” can be reduced as compared with a case where the Kelvin wiring has only parasitic resistance. Furthermore, if the lower limit of the range of the resistance value of the Kelvin wiring predetermined portion Pk is set large as the above-described resistance value, the “diverging current” and the “superimposed switching noise” can be more excellently reduced as described above.

### {Position of Kelvin Wiring Predetermined Portion Pk}

The position of the Kelvin wiring predetermined portion Pk is not particularly limited. However, the “diverging current” flows into the common Kelvin wiring Wkc from at least one of the individual Kelvin wirings Wki1 to Wkin of at least one of the switching elements SW1 to SWn and flows out from at least one of the individual Kelvin wirings Wki1 to Wkin of the other at least one of the switching elements SW1 to SWn, and therefore the Kelvin wiring predetermined portion Pk is preferably disposed in the individual Kelvin wirings Wki1 to Wkin corresponding to all the switching elements SW1 to SWn or in the common Kelvin wiring specific portion corresponding to all the switching elements SW1 to SWn from the viewpoint of reducing the “diverging current” and the “superimposition of switching noise” reliably.

In a case where the Kelvin wiring predetermined portion Pk is disposed in the individual Kelvin wirings Wki1 to Wkin of all the switching elements excluding one of the plurality of switching elements SW1 to SWn, the current value of the “diverging current” does not significantly depend on whether the Kelvin wiring predetermined portion Pk is disposed in one of the individual Kelvin wirings Wki1 to Wkin corresponding to the excluded one switching element. Therefore, also in an embodiment in which the Kelvin wiring predetermined portion Pk is disposed in the individual Kelvin wirings Wki1 to Wkin of all the switching elements excluding one of the plurality of switching elements SW1 to SWn, the “diverging current” and the “superimposition of switching noise” are reduced in the almost same manner as in an embodiment in which the Kelvin wiring predetermined portion Pk is disposed in the individual Kelvin wirings Wki1 to Wkin corresponding to all the switching elements SW1 to SWn, so that the former embodiment is also preferable.

Examples of the embodiment in which the Kelvin wiring predetermined portion Pk is disposed in the common Kelvin wiring specific portion corresponding to all the switching elements SW1 to SWn include, literally, an embodiment in which the Kelvin wiring predetermined portion Pk is the portions, in the common Kelvin wiring Wkc, between each pair of points to which a pair among the individual Kelvin wirings Wki1 to Wkin corresponding to a pair of adjacent switching elements among all the switching elements SW1 to SWn are connected, and in addition, an embodiment in which the Kelvin wiring predetermined portion Pk is the entire common Kelvin wiring Wkc, and an embodiment in which the Kelvin wiring predetermined portion Pk is the connection points between the common Kelvin wiring Wkc and the individual Kelvin wirings Wki1 to Wkin corresponding to all the switching elements SW1 to SWn and the circumference of the points.

### {Upper Limit of Resistance Value of Kelvin Wiring Predetermined Portion Pk}

Next, the upper limit of the resistance value of the Kelvin wiring predetermined portion Pk will be described.

The Kelvin wiring predetermined portion Pk preferably has a resistance value as large as possible from the viewpoint of reducing the diverging current of the main current into the Kelvin wiring Wk and reducing the switching noise superimposed on the diverging current. Therefore, the theoretical upper limit of the resistance value of the Kelvin wiring predetermined portion Pk is an infinite. In other words, theoretically, the resistance value of the Kelvin wiring predetermined portion Pk does not have an upper limit.

Meanwhile, from the viewpoint of controlling the switching elements SW1 to SWn, the sum of the resistance value of the Kelvin wiring predetermined portion Pk and the resistance value of the gate resistor Rg is to be equal to the recommended gate resistance value of the switching elements SW1 to SWn. However, the recommended gate resistance value of the switching elements SW1 to SWn is specified according to the specification (performance) of the switching elements SW1 to SWn, and therefore switching elements SW1 to SWn having no recommended gate resistance value may be developed in the future. Therefore, it is unreasonable to consider the recommended gate resistance value as a factor that restricts the upper limit of the resistance value of the Kelvin wiring predetermined portion Pk. However, a practical upper limit of the resistance value of the Kelvin wiring predetermined portion Pk may be set in consideration of the current situation. The recommended gate resistance value is generally several tens 22 to several hundreds Ω. For the recommended gate resistance value, future technical progress in switching elements is to be considered. Then, the practical upper limit of the resistance value of the Kelvin wiring predetermined portion Pk may be, for example, 1 kQ.

To summarize the above description, the resistance value of the Kelvin wiring predetermined portion Pk theoretically does not have an upper limit. However, practically, the resistance value of the Kelvin wiring predetermined portion Pk is preferably 1 kΩ or less.

### <<Aspect of Increase in Resistance of Kelvin Wiring Predetermined Portion Pk>>

The Kelvin wiring predetermined portion Pk may be a resistance element. In this way, the resistance value of the Kelvin wiring predetermined portion Pk can be easily increased.

The Kelvin wiring predetermined portion Pk may include a material having a high electrical resistivity. In this way, the resistance value of the Kelvin wiring predetermined portion Pk can be easily increased. Examples of the material having a high electrical resistivity include nichrome. Nichrome is preferable as a material of the switching module 100 because the linear expansion coefficient of nichrome is similar to that of copper and is relatively small. Note that the electrical resistivity of nichrome is 1.10×10⁻⁶ [Ω·m], and the electrical resistivity of copper is 1.68×10⁻⁸ [Ω·m].

The cross-sectional area of the Kelvin wiring predetermined portion Pk may be reduced. In this way, the resistance value of the Kelvin wiring predetermined portion Pk can be increased without changing the material of the Kelvin wiring predetermined portion Pk.

### {Operation of First Configuration Example}

Next, the operation of the first configuration example of the switching module 100 configured as described above will be described with reference to FIG. 1A.

Referring to FIG. 1A, when a control electrode drive signal instructing “ON” is input from the control electrode drive circuit to the control wiring terminal Tc, the plurality of switching elements SW1 to SWn are turned on. As a result, in each of the plurality of switching elements SW1 to SWn, a main current flows between the first electrode Ef and the second electrode Es. In this process, a part of the main current flows into the wirings among the individual Kelvin wirings Wki1 to Wkin corresponding to the elements having a relatively high source potential among the switching elements SW1 to SWn and diverges into the common Kelvin wiring Wkc, and this diverging current flows backward through the wirings among the individual Kelvin wirings Wki1 to Wkin corresponding to the elements having a relatively low source potential among the switching elements SW1 to SWn and merges into the main current in the wirings among the individual second electrode wirings Wsi1 to Wsin corresponding to these elements among the switching elements SW1 to SWn. Then, the switching noise caused by the wirings of the switching module 100 is superimposed on the diverging current. However, in the switching module 100, the Kelvin wiring predetermined portion Pk is disposed in the Kelvin wiring Wk, and the Kelvin wiring predetermined portion Pk is at least one of the individual Kelvin wirings Wki1 to Wkin corresponding to at least one of the plurality of switching elements SW1 to SWn and has a resistance value of 1 mΩ or more, or the Kelvin wiring predetermined portion Pk is at least a part of the common Kelvin wiring Wkc and has a resistance value of 3 mΩ or more, and thus the resistance value reduces the diverging current and the switching noise superimposed on the diverging current. This reduction reduces an excess of a deviation in timing of turn-on or turn-off between the plurality of switching elements SW1 to SWn over the allowable limit.

### Second Configuration Example

In the second configuration example, the following configuration and operation are different from those in the first configuration example, and the other configuration and operation are the same as those in the first configuration example. Therefore, only this difference will be described.

FIG. 1B is a circuit diagram showing an outline of the second configuration example of the switching module 100 according to an embodiment of the present disclosure.

Referring to FIG. 1B, in the second configuration example of the switching module 100, the control electrode wiring Wc includes a plurality of single control electrode wirings Wcl to Wen. One ends of the plurality of single control electrode wirings Wel to Wen are connected to the plurality of control wiring terminals Tel to Ten, respectively. To the plurality of control wiring terminals Tel to Ten, a plurality of different control electrode drive signals are input. As a result, the plurality of switching elements SW1 to SWn operate so as to be different from each other. In the second configuration example, the plurality of switching elements SW1 to SWn are designed to be turned on at predetermined different on-timing and to be turned off at predetermined different off-timing, and allowable limits are determined for the deviation from the on-timing and the deviation from the off-timing. The second configuration example of the switching module 100 can be applied to such a switching module in which the plurality of switching elements SW1 to SWn operates so as to be different from each other.

### SPECIFIC EMBODIMENTS

Next, a specific embodiment of a switching module 100 according to an embodiment of the present disclosure will be described. Hereinafter, a specific embodiment of the first configuration example of the switching module 100 will be described, and description of a specific embodiment of the second configuration example of the switching module 100 will be omitted because the specific embodiment of the second configuration example is different from that of the first configuration example only in the configuration of the control electrode wiring Wc.

### {Main Component}

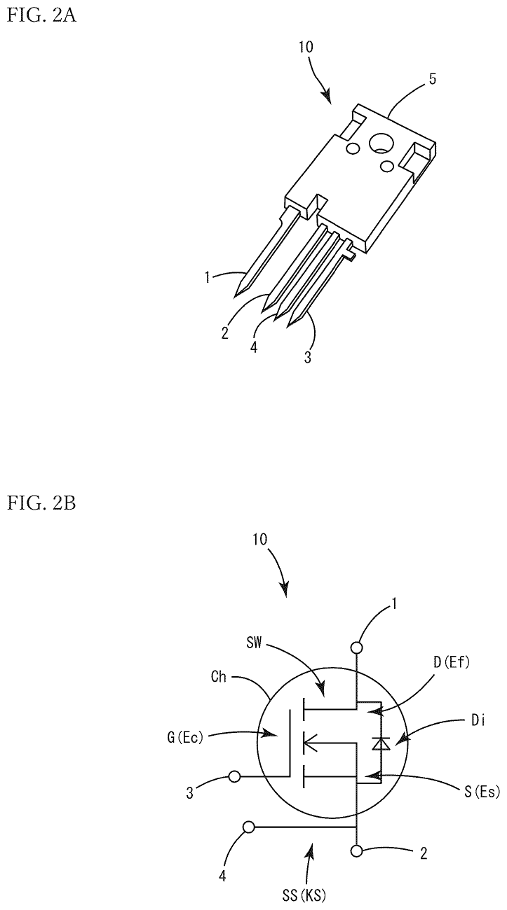

First, main components included in the switching module 100 will be described. FIG. 2A is a perspective view showing an appearance of a discrete component 10 incorporating a single switching element SW, and FIG. 2B is a circuit diagram showing an equivalent circuit of the discrete component 10 of FIG. 2A. The structure of the discrete component 10 is well known, and therefore will be briefly described.

Referring to FIGS. 2A and 2B, the discrete component 10 is a four-terminal power semiconductor and includes a resin encapsulator 5 and lead terminals 1 to 4. The resin encapsulator 5 includes a chip Ch incorporating the single switching element SW, wirings electrically connecting the switching element SW of the chip Ch to the lead terminals 1 to 4, and a resin body encapsulating the chip Ch and the wirings. The single switching element SW is, for example, an n metal oxide semiconductor field effect transistor (NMOSFET), and includes a drain D, a source S, a gate G, and a source sense wiring SS. The drain D, the source S, the gate G, and the source sense wiring SS are connected to the lead terminals 1, 2, 3, and 4, respectively. The drain D, the source S, the gate G, and the source sense wiring SS correspond to the first electrode Ef, the second electrode Es, the control electrode Ec, and the Kelvin sense wiring KS, respectively. Here, a diode Di is connected between the drain and the source of the NMOSFET so that the forward direction of the diode is opposite to the forward direction of the NMOSFET, and this diode is a body diode (parasitic diode).

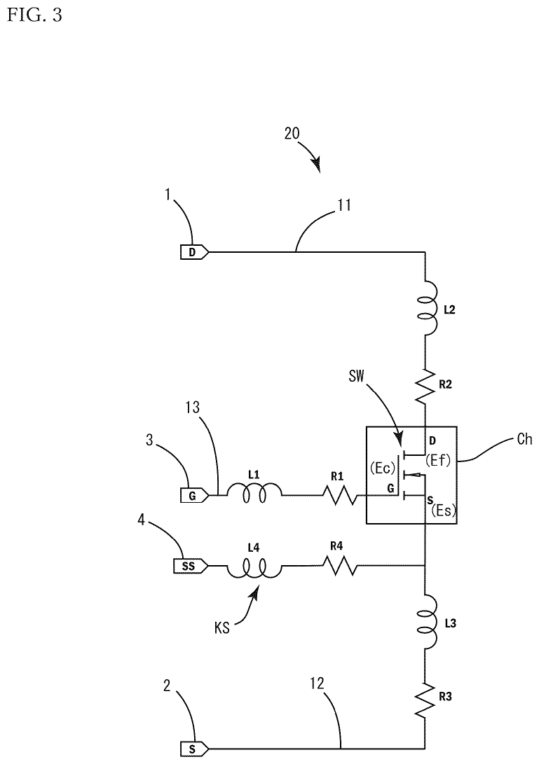

FIG. 3 is a circuit diagram showing an equivalent circuit of one switching element SW of a module 20 incorporating a plurality of switching elements connected in parallel to each other and internal wirings 11 to 13 and KS related to the switching element SW. The module 20 is a four-terminal power semiconductor and includes a plurality of chips Ch. FIG. 3 shows one of the chips Ch and members related to the chip. Referring to FIG. 3, the switching element SW of the chip Ch is, for example, an NMOSFET, and a drain D (Ef), a source (Es), and a gate G (Ec) are connected to a terminal (drain terminal) 1, a terminal (source terminal) 2, and a terminal (gate terminal) 3 via the internal wirings 11, 12, and 13, respectively. In addition, a source sense wiring (Kelvin sense wiring KS) is connected to a source sense terminal 4. The internal wirings 11,12, and 13 and the Kelvin sense wiring KS have parasitic resistances R1 to R4 and parasitic inductances L1 to L4.

FIG. 4 is a circuit diagram showing an example of a configuration of a switching module 100A that embodies the first configuration example of the switching module 100 of FIG. 1A using the discrete component 10 incorporating the single switching element SW of FIGS. 2A and 2B. FIG. 4 shows only a configuration related to technical features of the first configuration example of the switching module 100 of FIG. 1A in order to facilitate understanding of the main points of the present invention.

Referring to FIG. 4, the switching module 100A includes a substrate and a plurality of discrete components 10 mounted on the substrate. For example, a patterned first electrode wiring Wf (omitted in FIG. 4), a second electrode wiring Ws, a control electrode wiring Wc (omitted in FIG. 4), and a Kelvin wiring Wk are provided on the substrate, and the plurality of discrete components 10 are mounted on pads appropriately connected to the wirings Wf, Ws, Wc, and Wk, respectively. Thus, the terminals (lead terminals) 1 to 4 of the plurality of discrete components 10 are basically connected to the corresponding wirings Wf, Ws, Wc, and Wk, respectively. However, in the Kelvin wiring Wk, the terminals 4 of all the discrete components 10 are each connected to a common Kelvin wiring Wkc by a Kelvin wiring predetermined portion Pk. Therefore, individual Kelvin wirings Wki1 to Wkin include the Kelvin wiring predetermined portion Pk and a Kelvin sense wiring KS corresponding to each of switching elements SW1 to SWn. The individual Kelvin wirings Wki1 to Wkin corresponding to the plurality of switching elements SW1 to SWn respectively are connected to the common Kelvin wiring Wkc at an interval. Note that the terminals 2 of the plurality of discrete components 10 (sources of the plurality of switching elements SW1 to SWn) are connected to a common second electrode wiring Wsc by individual second electrode wirings Wsi1 to Wsin, respectively. Furthermore, a first wiring terminal Tf, a second wiring terminal Ts, a control wiring terminal Tc, and a Kelvin wiring terminal Tk are appropriately provided on the substrate. The first wiring terminal Tf and the control wiring terminal Tc are omitted in FIG. 4.

The Kelvin wiring predetermined portion Pk includes, for example, a chip including a resistance element. However, the Kelvin wiring predetermined portion Pk may include a material having a high electrical resistivity, such as nichrome, or may have a cross-sectional area smaller than the cross-sectional area of the common second electrode wiring Wsc.

Next, an operation of the switching module 100A having the above-described configuration will be described.

Referring to FIGS. 2A and 4, when a control electrode drive signal instructing “ON” is input from a control electrode drive circuit to the control wiring terminal Tc, the plurality of switching elements SW1 to SWn are turned on, and in each of the plurality of switching elements SW1 to SWn, a main current Im flows between a drain D (Ef) and a source S (Es). Here, the source potentials of the switching elements SW1 to SWn are assumed to become lower in this order. In this process, a part of the main current Im flows into the individual Kelvin wirings Wki1 to Wkir of the switching elements SW1 to SWr having a relatively high source potential (r is an integer of 2 or more and n−1 or less) and diverges into the common Kelvin wiring Wkc, and this diverging current flows backward through the individual Kelvin wirings Wkir+1 to Wkin of the switching elements SWr+1 to SWn having a relatively low source potential and merges into the main current in the individual second electrode wirings Wsir+1 to Wsin corresponding to the switching elements SWr+1 to SWn. Then, the switching noise caused by the wirings of the switching module 100 is superimposed on the diverging current.

However, since the Kelvin wiring predetermined portion Pk has a resistance value of 1 mΩ or more, this resistance value reduces the diverging current Ik and the switching noise superimposed on the diverging current Ik, resulting in reduction of an excess of a deviation in timing of switching between the plurality of switching elements SW1 to SWn over the allowable limit. In addition, since the Kelvin wiring predetermined portion Pk is provided in all the individual Kelvin wirings Wki1 to Wkin, the “diverging current” and the “superimposed switching noise” are efficiently reduced. Furthermore, since the Kelvin wiring predetermined portion Pk connects the terminal 4 of the Kelvin wiring of the discrete component 10 and the common Kelvin wiring Wkc, a generic discrete component 10 can be used. In this case, one or both of the Kelvin sense wiring KS (source sense wiring SS) and the terminal 4 in the discrete component 10 may be the Kelvin wiring predetermined portion Pk. In this case, the discrete component 10 is a dedicated component.

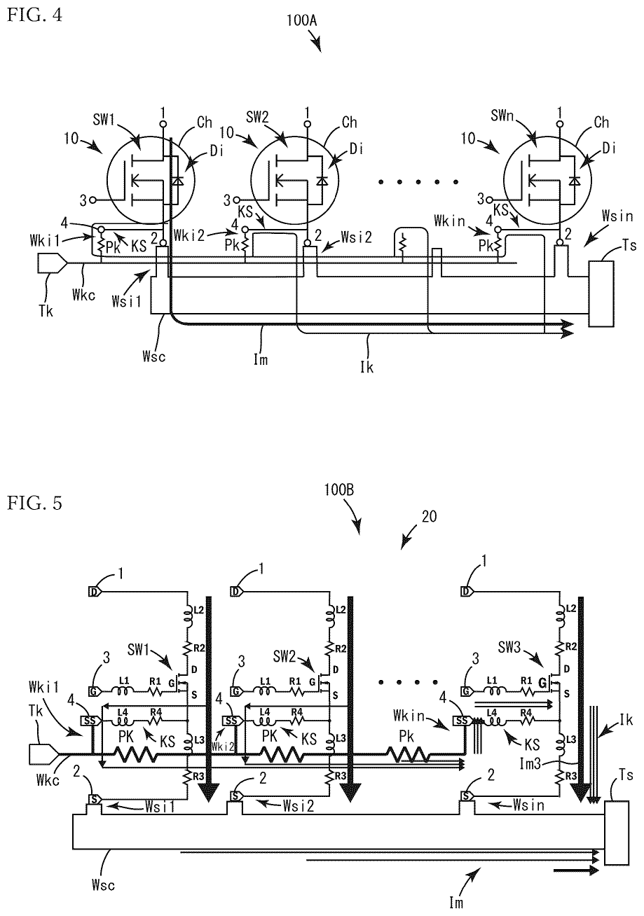

FIG. 5 is a circuit diagram showing an example of a configuration of a switching module 100B that embodies the first configuration example of the switching module 100 of FIG. 1A using the module 20 incorporating a plurality of switching elements SW connected in parallel to each other of FIG. 3. FIG. 5 shows only a configuration related to technical features of the first configuration example of the switching module 100 of FIG. 1A in order to facilitate understanding of the main points of the present invention.

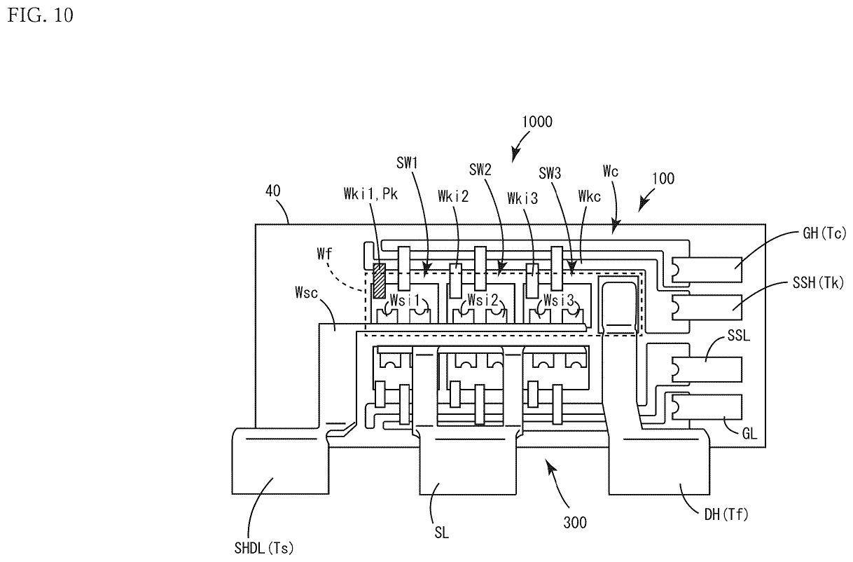

Referring to FIG. 5, the switching module 100B includes a base member 40 (see FIG. 10) and the module 20 mounted on the base member 40. For example, a first electrode wiring Wf (omitted in FIG. 5), a second electrode wiring Ws, a control electrode wiring Wc (omitted in FIG. 5), and a Kelvin wiring Wk are provided on the base, and the module 20 is mounted so as to be appropriately connected to the wirings Wf, Ws, Wc, and Wk. Thus, the terminals 1 to 4 of the module 20 are basically connected to the corresponding wirings Wf, Ws, Wc, and Wk, respectively. However, in the Kelvin wiring Wk, the terminal 4 of each chip Ch of the module 20 (see FIG. 3) is connected to a common Kelvin wiring Wkc by a predetermined wiring. Therefore, individual Kelvin wirings Wki1 to Wkin include the predetermined wiring and a Kelvin sense wiring KS corresponding to each of switching elements SW1 to SWn. The individual Kelvin wirings Wki1 to Wkin corresponding to the plurality of switching elements SW1 to SWn respectively are connected to the common Kelvin wiring Wkc at an interval. A Kelvin wiring predetermined portion Pk is disposed in portions (common Kelvin wiring specific portion), in the common Kelvin wiring Wkc, between each pair of points to which a pair among the individual Kelvin wirings Wki1 to Wkin corresponding a pair of adjacent switching elements among all the switching elements SW1 to SWn are connected, respectively.

Note that the source terminals 2 of the plurality of switching elements SW1 to SWn are connected to a common second electrode wiring Wsc by individual second electrode wirings Wsi1 to Wsin, respectively. Furthermore, a first wiring terminal Tf, a second wiring terminal Ts, a control wiring terminal Tc, and a Kelvin wiring terminal Tk are appropriately provided on the base member 40. The first wiring terminal Tf and the control wiring terminal Tc are omitted in FIG. 5.

Next, an operation of the switching module 100B having the above-described configuration will be described.

Referring to FIGS. 3 and 5, when a control electrode drive signal instructing “ON” is input from a control electrode drive circuit to the control wiring terminal Tc, the plurality of switching elements SW1 to SWn are turned on, and in each of the plurality of switching elements SW1 to SWn, a main current Im flows between a drain D (Ef) and a source S (Es). Here, the source potentials of the switching elements SW1 to SWn are assumed to become lower in this order. A part of the main current Im flows into the individual Kelvin wirings Wki1 to Wkir of the switching elements SW1 to SWr having a relatively high source potential (r is an integer of 2 or more and n−1 or less) and diverges into the common Kelvin wiring Wkc, and this diverging current flows backward through the individual Kelvin wirings Wkir+1 to Wkin of the switching elements SWr+1 to SWn having a relatively low source potential and merges into the main current in the individual second electrode wirings Wsir+1 to Wsin corresponding to the switching elements SWr+1 to SWn. Then, the switching noise caused by the wirings of the switching module 100B is superimposed on the diverging current Ik.

However, since the Kelvin wiring predetermined portion Pk has a resistance value of 3 mΩ or more, this high resistance value reduces the diverging current Ik and the switching noise superimposed on the diverging current Ik, resulting in reduction of an excess of a deviation in timing of switching between the plurality of switching elements SW1 to SWn over the allowable limit. In addition, since the Kelvin wiring predetermined portion Pk is provided in the common Kelvin wiring specific portion corresponding to all the switching elements SW1 to SWn in the common Kelvin wiring Wkc, the “diverging current” and the “superimposed switching noise” are efficiently reduced. Furthermore, since the Kelvin wiring predetermined portion Pk is provided outside the module 20, a generic module 20 can be used. In this case, a Kelvin wiring Wk having the Kelvin wiring predetermined portion Pk may be provided inside the module 20. In this case, the module 20 is a dedicated component.

### [Simulation]

The first and the second simulations were performed on the arrangement and the resistance value of the Kelvin wiring predetermined portion Pk.

### <First Simulation>

In the first simulation, in a switching module 100C, a Kelvin wiring predetermined portion Pk was disposed in individual Kelvin wirings corresponding to all switching elements, and the resistance value of the Kelvin wiring predetermined portion Pk was changed.

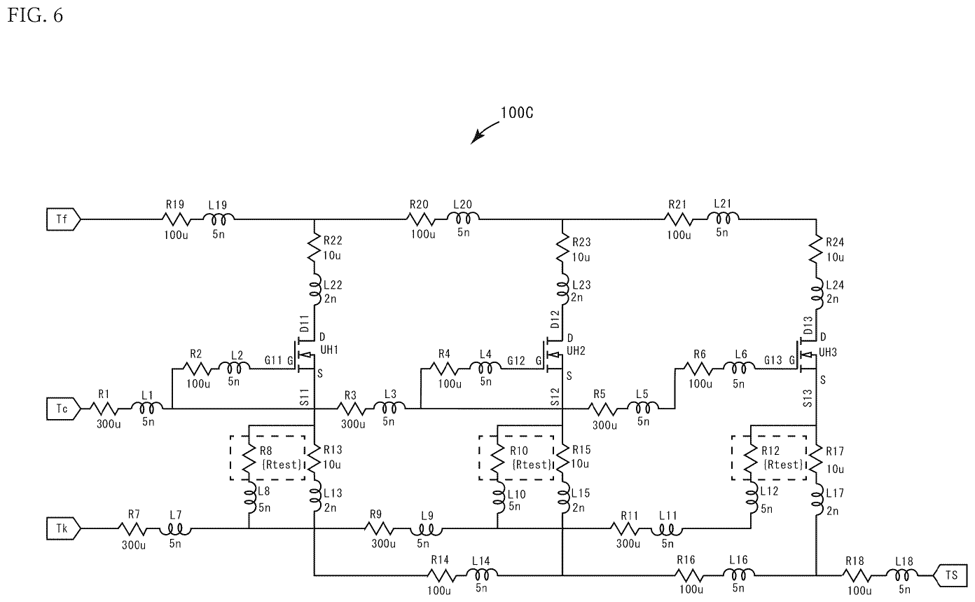

FIG. 6 is a circuit diagram showing an equivalent circuit of the switching module 100C in the first simulation. This simulation was performed for a full-bridge current resonance circuit including a pair of high-side switching modules, one of which is the switching module 100C of the present invention. In this full-bridge current resonance circuit, the power supply voltage was set to DC 500 V, the load coil inductance was set to 800 nH, and the load capacitor capacitance was set to 300 nF.

Referring to FIG. 6, the switching module 100C includes first to third switching elements UH1 to UH3 constituted by NMOSFETs. In the switching module 100C, the same parasitic impedance was set for a drain wiring (first electrode wiring), a source wiring (second electrode wiring), a gate wiring (control electrode wiring), and a Kelvin wiring corresponding to each of the first to the third switching elements UH1 to UH3. Therefore, in the switching module 100C, it is assumed that the source potentials of the first switching element UH1, the second switching element UH2, and the third switching element UH3 become lower in this order (the source potential of the third switching element UH3 is the lowest).

In this simulation, the resistance values Rtest of the resistances R8, R10, and R12, which are surrounded by a dotted square, in the individual Kelvin wiring of each of the first to the third switching elements UH1 to UH3 were used as a parameter and changed to the resistance value of the parasitic resistance (100μΩ) and 10 times (1 mΩ), 20 times (2 mΩ), 40 times (4 mΩ), 100 times (10 mΩ), 200 times (20 mΩ), 500 times (50 mΩ), and 1000 times (100 mΩ) the resistance value of the parasitic resistance, for performing the simulation. Regarding the current of the individual Kelvin wiring, the current in the direction from the source toward a common Kelvin wiring is treated as a positive current.

For the full-bridge current resonance circuit set as described above, a simulation was performed on the operation in the period before and after turning on of the first to the third switching elements UH1 to UH3, and the current values of the individual Kelvin wirings were acquired.

### <<Results of Simulation>>

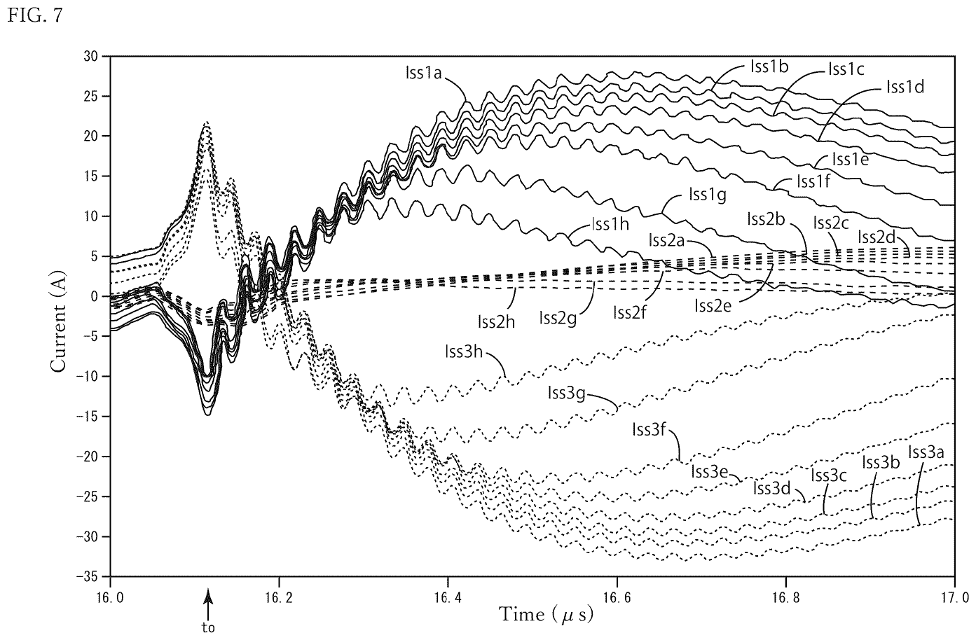

FIG. 7 is a graph showing the current values of the individual Kelvin wirings in the simulation using the equivalent circuit of FIG. 6. Note that FIG. 7 was created by tracing the waveform images of the currents actually obtained, and the waveforms are not strictly accurate. In FIG. 7, the horizontal axis represents the elapsed time (unit: uS) in the simulation, and the vertical axis represents the current (unit: A). A solid line, a broken line, and a dotted line respectively represent a current of the individual Kelvin wiring of the first switching element UH1, a current of the individual Kelvin wiring of the second switching element UH2, and a current of the individual Kelvin wiring of the third switching element UH3.

In FIG. 7, reference signs ISS1a to ISS1h of the solid curve indicate the currents of the individual Kelvin wiring of the first switching element UH1, reference signs ISS2a to ISS2h of the broken curve indicate the currents of the individual Kelvin wiring of the second switching element UH2, and reference signs ISS3a to ISS3h of the dotted curve indicate the currents of the individual Kelvin wiring of the third switching element UH3. The suffixes a to h in these reference signs indicate that the curves corresponding to these suffixes represent the currents in a case where the resistance values of the individual Kelvin wiring are the resistance value of the parasitic resistance (100μΩ) and 10 times (1 mΩ), 20 times (2 mΩ), 40 times (4 mΩ), 100 times (10 mΩ), 200 times (20 mΩ), 500 times (50 mΩ), and 1000 times (100 mΩ) the resistance value of the parasitic resistance, respectively. Furthermore, “to” on the horizontal axis indicates the time when the first to the third switching elements UH1 to UH3 are turned on (hereinafter, sometimes simply referred to as turn-on).

### {Generation of “Diverging Current”}

Referring to FIG. 7, the currents ISS1a to ISS1h of the individual Kelvin wiring of the first switching element UH1 flow in the positive direction from almost immediately after the turn-on. The currents ISS2a to ISS2h of the individual Kelvin wiring of the second switching element UH2 flow in the positive direction a short time later after the turn-on. The magnitudes of the currents ISS2a to ISS2h of the individual Kelvin wiring of the second switching element UH2 are smaller than the magnitudes of the currents ISSla to ISSIh of the individual Kelvin wiring of the first switching element UH1. The currents ISS3a to ISS3h of the individual Kelvin wiring of the third switching element UH3 flow in the backward direction from almost immediately after the turn-on. The absolute values of the respective sums of the current values of the currents ISS1a to ISS1h of the individual Kelvin wiring of the first switching element UH1 and the current values of the currents ISS2a to ISS2h of the individual Kelvin wiring of the second switching element UH2 are approximately equal to the respective absolute values of the current values of the currents ISS3a to ISS3h of the individual Kelvin wiring of the third switching element UH3. From these results, it is presumed that the currents ISS1a to ISS1h of the individual Kelvin wiring of the first switching element UH1 and the currents ISS2a to ISS2h of the individual Kelvin wiring of the second switching element UH2 flow into the common Kelvin wiring and flow out from the individual Kelvin wiring of the third switching element UH3. Furthermore, it is presumed that the source potentials of the first switching element UH1, the second switching element UH2, and the third switching element UH3 become lower in this order (the source potential of the third switching element UH3 is the lowest). From these, it was estimated that the “diverging current” was generated.

### {Superimposition of Switching Noise}

The currents ISS1a to ISS1h of the individual Kelvin wiring of the first switching element UH1 and the currents ISS3a to ISS3h of the individual Kelvin wiring of the third switching element UH3 increase from the turn-on, which is a trigger, while fluctuating, and gradually decrease. From this result, it is estimated that the switching noise caused by the wiring parasitic impedance is particularly superimposed on the currents ISS1a to ISS1h of the individual Kelvin wiring of the first switching element UH1 and the currents ISS3a to ISS3h of the individual Kelvin wiring of the third switching element UH3, resulting in the large fluctuation in the currents ISS1a to ISS1h of the individual Kelvin wiring of the first switching element UH1 and the currents ISS3a to ISS3h of the individual Kelvin wiring of the third switching element UH3. Furthermore, it is estimated that a deviation in timing of switching between the first to the third switching elements UH1 to UH3 exceeds the allowable limit when various adverse conditions coincide with the large fluctuation in the currents ISS1a to ISS1h of the individual Kelvin wiring of the first switching element UH1 and the currents ISS3a to ISS3h of the individual Kelvin wiring of the third switching element UH3.

### {Effect of Increase in Resistance Value of Individual Kelvin Wiring}

Next, focusing on the resistance value of each individual Kelvin wiring, as the resistance value of the individual Kelvin wiring increases, the fluctuation in the current of the individual Kelvin wiring monotonously decreases.

In a case where the resistance value of the individual Kelvin wiring is the resistance value of the parasitic resistance (100μΩ), the magnitudes of the fluctuations in the current ISS1a of the individual Kelvin wiring of the first switching element UH1 and the current ISS3a of the individual Kelvin wiring of the third switching element UH3 are at a certain level. Meanwhile, in a case where the resistance value of the individual Kelvin wiring is 10 times (1 mΩ) the resistance value of the parasitic resistance, the fluctuations in the current ISS1b of the individual Kelvin wiring of the first switching element UH1 and the current ISS3b of the individual Kelvin wiring of the third switching element UH3 are clearly smaller than those in a case where the resistance value of the individual Kelvin wiring is the resistance value of the parasitic resistance (100μΩ).

In a case where the resistance value of the individual Kelvin wiring is 40 times (4 mΩ) the resistance value of the parasitic resistance, the fluctuations in the current ISS1d of the individual Kelvin wiring of the first switching element UH1 and the current ISS3d of the individual Kelvin wiring of the third switching element UH3 are effectively reduced as compared with a case where the resistance value of the individual Kelvin wiring is the resistance value of the parasitic resistance (100μΩ).

In a case where the resistance value of the individual Kelvin wiring is 100 times (10 mΩ) the resistance value of the parasitic resistance, the fluctuations in the current ISS1e of the individual Kelvin wiring of the first switching element UH1 and the current ISS3e of the individual Kelvin wiring of the third switching element UH3 are excellently reduced as compared with a case where the resistance value of the individual Kelvin wiring is the resistance value of the parasitic resistance (100μΩ).

In a case where the resistance value of the individual Kelvin wiring is 1000 times (100 mΩ) the resistance value of the parasitic resistance, the fluctuations in the current ISS1h of the individual Kelvin wiring of the first switching element UH1 and the current ISS3h of the individual Kelvin wiring of the third switching element UH3 are remarkably reduced as compared with a case where the resistance value of the individual Kelvin wiring is the resistance value of the parasitic resistance (100μΩ).

### SUMMARY

First, providing the Kelvin wiring predetermined portion Pk in the individual Kelvin wirings corresponding to all the switching elements UH1 to UH3 is effective as a method of reducing the “diverging current” and the “superimposed switching noise”. Second, in the present simulation, the number of the switching elements is three, but it is presumed that a similar effect is obtained even when the number of switching elements is four or more. Third, if the resistance value of the individual Kelvin wiring is 10 times (1 mΩ) or more the resistance value of the parasitic resistance, the “diverging current” and the “superimposed switching noise” are reduced to such an extent that the “diverging current” and the “superimposed switching noise” can be clearly distinguished from those in a case where the resistance value of the individual Kelvin wiring is the resistance value of the parasitic resistance (100μΩ).

### <Second Simulation>

In the second simulation, in a switching module 100D, a Kelvin wiring predetermined portion Pk was set to portions (common Kelvin wiring specific portion), in a common Kelvin wiring, between each pair of points to which a pair of individual Kelvin wirings of a pair of adjacent switching elements among all the switching elements UH1 to UH3 were connected, and the resistance value of the common Kelvin wiring specific portion was changed.

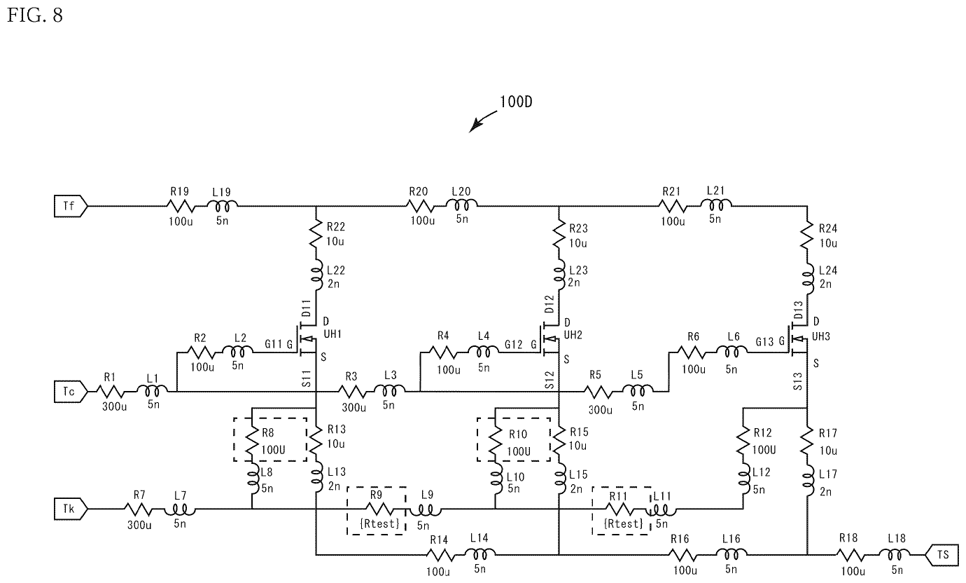

FIG. 8 is a circuit diagram showing an equivalent circuit of the switching module 100D in the second simulation. This simulation was performed on a full-bridge current resonance circuit configured and set similarly to that in the first simulation.

Referring to FIG. 8, in the switching module 100D, the resistances R9 and R11 surrounded by a dotted square in the common Kelvin wiring (resistance of the common Kelvin wiring specific portion) were set as the Kelvin wiring predetermined portion Pk. Then, the resistances R8, R10, and R12 of the individual Kelvin wirings of the first to the third switching elements UH1 to UH3 were set to 100μΩ, which was the resistance value of the parasitic resistance. Except for the above-described points, the switching module 100D is the same as the switching module 100C in FIG. 6.

For the switching module 100D, a simulation was performed with the resistance value Rtest as a parameter changed to the resistance value of the parasitic resistance (300μΩ) and to 333 times (100 mΩ) and 1000 times (300 mΩ) the resistance value of the parasitic resistance, and the current values of the individual Kelvin wirings were acquired in the period before and after the turn-on of the first to the third switching elements UH1 to UH3.

### <<Results of Simulation>>

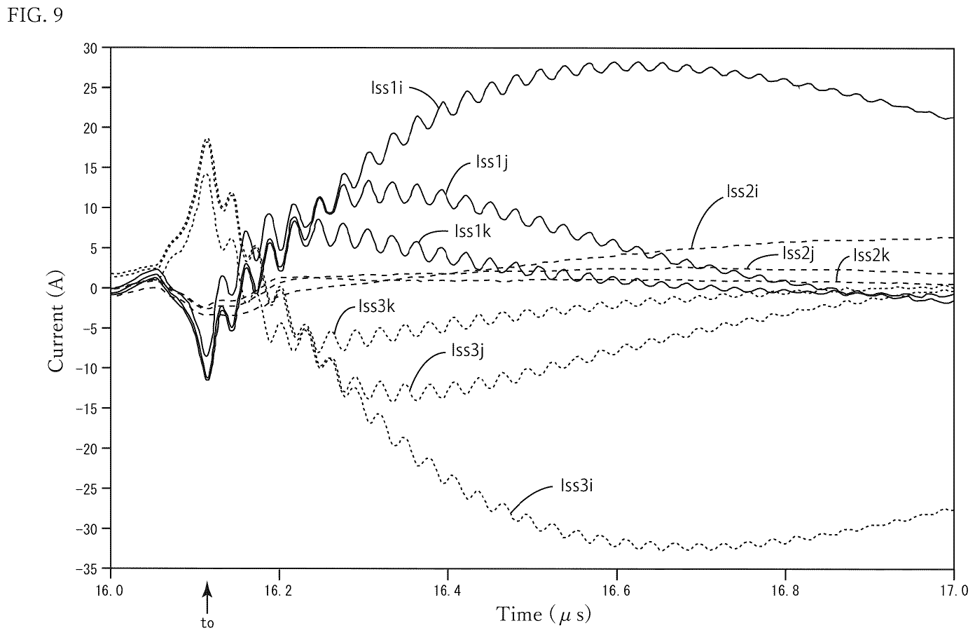

FIG. 9 is a graph showing the current values of the individual Kelvin wirings in the simulation using the equivalent circuit of FIG. 8. Note that FIG. 9 was created by tracing the waveform images of the currents actually obtained, and the waveforms are not strictly accurate. In FIG. 9, the horizontal axis represents the elapsed time (unit: μS) in the simulation, and the vertical axis represents the current (unit: A). A solid line, a broken line, and a dotted line respectively represent a current of the individual Kelvin wiring of the first switching element UH1, a current of the individual Kelvin wiring of the second switching element UH2, and a current of the individual Kelvin wiring of the third switching element UH3. In FIG. 9, reference signs ISS1i to ISS1k of the solid curve indicate the currents of the individual Kelvin wiring of the first switching element UH1, reference signs ISS2i to ISS2k of the broken curve indicate the currents of the individual Kelvin wiring of the second switching element UH2, and reference signs ISS3i to ISS3k of the dotted curve indicate the currents of the individual Kelvin wiring of the third switching element UH3. The suffixes i to k in these reference signs indicate that the curves corresponding to these suffixes represent the currents in a case where the resistance value of the common Kelvin wiring specific portion is the resistance value of the parasitic resistance (300μΩ), and 333 times (100 mΩ) and 1000 times (300 mΩ) the resistance value of the parasitic resistance, respectively. Furthermore, “to” on the horizontal axis indicates the turn-on time.

Referring to FIG. 9, as can be understood at a glance, FIGS. 9 and 7 are similar in the aspects of generation of the “diverging current” related to the currents of the individual Kelvin wirings of the first to the third switching elements UH1 to UH3, the “superimposition of the switching noise”, and the decrease of fluctuation in the current of the individual Kelvin wiring with respect to the increase in the resistance value of the individual Kelvin wiring. Therefore, description of the aspects will be omitted.

### {Effect of Increase in Resistance Value of Common Kelvin Wiring Specific Portion}

In a case where the resistance value of the common Kelvin wiring specific portion is the resistance value of the parasitic resistance (300μΩ), as in FIG. 7, the magnitudes of the fluctuations in the current ISS1i of the individual Kelvin wiring of the first switching element UH1 and the current ISS3i of the individual Kelvin wiring of the third switching element UH3 are at a certain level.

Meanwhile, in a case where the resistance value of the common Kelvin wiring specific portion is 333 times (100 mΩ) the resistance value of the parasitic resistance, the fluctuations in the current ISSj of the individual Kelvin wiring of the first switching element UH1 and the current ISS3j of the individual Kelvin wiring of the third switching element UH3 are remarkably reduced as compared with a case where the resistance value of the common Kelvin wiring specific portion is the resistance value of the parasitic resistance (300μΩ).

In a case where the resistance value of the common Kelvin wiring specific portion is 1000 times (300 mΩ) the resistance value of the parasitic resistance, the fluctuations in the current ISS1k of the individual Kelvin wiring of the first switching element UH1 and the current ISS3k of the individual Kelvin wiring of the third switching element UH3 are very remarkably reduced as compared with a case where the resistance value of the common Kelvin wiring specific portion is the resistance value of the parasitic resistance (300μΩ).

Although not shown in FIG. 9, it has been confirmed that in a case where the resistance value of the common Kelvin wiring specific portion is 10 times (3 mΩ) the resistance value of the parasitic resistance, the fluctuations in the current ISS1 of the individual Kelvin wiring of the first switching element UH1 and the current ISS3 of the individual Kelvin wiring of the third switching element UH3 are clearly smaller than those in a case where the resistance value of the common Kelvin wiring specific portion is the resistance value of the parasitic resistance (300μΩ). Furthermore, from the above results, it is estimated that in a case where the resistance value of the common Kelvin wiring specific portion is 40 times (12 mΩ) the resistance value of the parasitic resistance, the fluctuations in the current ISS1 of the individual Kelvin wiring of the first switching element UH1 and the current ISS3 of the individual Kelvin wiring of the third switching element UH3 are excellently reduced as compared with a case where the resistance value of the common Kelvin wiring specific portion is the resistance value of the parasitic resistance (300μΩ).

Furthermore, from the above results, it is estimated that in a case where the resistance value of the common Kelvin wiring specific portion is 100 times (30 mΩ) the resistance value of the parasitic resistance, the fluctuations in the current ISS1 of the individual Kelvin wiring of the first switching element UH1 and the current ISS3 of the individual Kelvin wiring of the third switching element UH3 are very excellently reduced as compared with a case where the resistance value of the common Kelvin wiring specific portion is the resistance value of the parasitic resistance (300μΩ).

### SUMMARY

First, providing the Kelvin wiring predetermined portion Pk in the common Kelvin wiring specific portion corresponding to all the switching elements UH1 to UH3 is more effective as a method of reducing the “diverging current” and the “superimposed switching noise” than providing the Kelvin wiring predetermined portion Pk in the individual Kelvin wirings corresponding to all the switching elements UH1 to UH3. Second, in the present simulation, the number of the switching elements is three, but it is presumed that a similar effect is obtained even when the number of switching elements is four or more. Third, if the resistance value of the common Kelvin wiring specific portion is 10 times (3 mΩ) or more the resistance value of the parasitic resistance, the “diverging current” and the “superimposed switching noise” are reduced to such an extent that the “diverging current” and the “superimposed switching noise” can be clearly distinguished from those in a case where the resistance value of the common Kelvin wiring specific portion is the resistance value of the parasitic resistance (100μΩ).

### State of Mounting of Switching Module

FIG. 10 is a view illustrating an appearance of a state of mounting of a full-bridge current resonance circuit 1000 in which the switching module 100 of FIG. 1A is used as a high-side switching module 100.

Referring FIG. 10, in the full-bridge current resonance circuit 1000, the switching module 100 of FIG. 1A is used as the high-side switching module 100. A low-side switching module 300 includes a switching module to which the present invention is not applied. The full-bridge current resonance circuit 1000 includes a base member 40. In the base member 40, a module 20 is embedded that includes chips Ch of switching elements SW1 to SW3. On the upper surface of the module 20, three pads corresponding to the switching elements SW1 to SW3 are formed. To these pads, individual second electrode wirings Wsi1 to Wsi3 corresponding to the three switching elements SW1 to SW3 are connected, the individual second electrode wirings Wsi1 to Wsi3 are connected to a distal end of a common second electrode wiring Wsc, and an SHDL terminal (second wiring terminal Ts) is connected to a base end of the common second electrode wiring Wsc. The individual second electrode wirings Wsi1 to Wsi3, the common second electrode wiring Wsc, and the SHDL terminal are integrated and constituted by a single member. On the base member 40, a common Kelvin wiring Wkc is provided along the three pads, and the three pads and the common Kelvin wiring Wkc are connected by individual Kelvin wirings Wki1 to Wki3. Among the individual Kelvin wirings Wki1 to Wki3n, the individual Kelvin wiring Wki1 corresponding to the first switching element SW1 is configured as a Kelvin wiring predetermined portion Pk. In a case where the kelvin wiring predetermined portion Pk is constituted by a chip of a resistance element, the chip is disposed in this portion. The common Kelvin wiring Wkc has a base end connected to an SSH terminal (Kelvin wiring terminal Tk). A first electrode wiring Wf is provided so as to be positioned below the chips of the switching elements SW1 to SW3, and is connected to a DH terminal (first wiring terminal Tf). On the base member 40, a control electrode wiring Wc is provided so as to be connected to the three pads. A base end of the control electrode wiring Wc is connected to a GH terminal (control wiring terminal Tc). Note that reference signs SL, GL, and SSL denote a source wiring terminal (second wiring terminal), a gate wiring terminal (control wiring terminal), and a source sense wiring terminal (Kelvin wiring terminal) of the low-side switching module 300, respectively. As described above, if the switching module 100 of FIG. 1A is mounted, the resistance of the Kelvin wiring predetermined portion Pk can be easily increased.

### OTHER EMBODIMENTS

As shown in FIG. 4 or 5, a switching module may be configured that embodies the second configuration example using the discrete component 10 or the module 20.

In the switching module 100A of FIG. 4 in which the discrete component 10 is embodied, the Kelvin wiring predetermined portion Pk may be provided in the common Kelvin wiring Wkc as shown in FIG. 5.

In the switching module 100B of FIG. 5 embodied using the module 20, the Kelvin wiring predetermined portion Pk may be provided in the individual Kelvin wirings Wki1 to Wkin as shown in FIG. 4.

In the switching module 100A of FIG. 4, the Kelvin wiring predetermined portion Pk may be disposed in the individual Kelvin wirings Wki1 to Wkin of all the switching elements excluding one of the plurality of switching elements SW1 to SWn.

From the above description, many modifications and other embodiments are apparent to those skilled in the art. Therefore, the above description is to be interpreted only as an example.

The switching module of the present invention is useful as a switching module that includes a plurality of switching elements each having a Kelvin-connected wiring and connected in parallel to each other, and is capable of reducing an excess of a deviation in timing of turn-on or turn-off between the switching elements over an allowable limit.

What is claimed is:

1. A switching module comprising:
a plurality of switching elements connected in parallel, the plurality of switching elements each including a first electrode, a second electrode, and a control electrode that controls a main current flowing between the first electrode and the second electrode by a potential difference with respect to the second electrode;
a first electrode wiring electrically connected to the first electrode of each of the plurality of switching elements;
a second electrode wiring electrically connected to the second electrode of each of the plurality of switching elements;
a control electrode wiring electrically connected to the control electrode of each of the plurality of switching elements; and
a Kelvin wiring including a common Kelvin wiring and individual Kelvin wirings electrically connecting the common Kelvin wiring to the second electrode of each of the plurality of switching elements, wherein
the Kelvin wiring has a Kelvin wiring predetermined portion that is at least a part of the Kelvin wiring, and
the Kelvin wiring predetermined portion is at least one of the individual Kelvin wirings corresponding to at least one of the plurality of switching elements and has a resistance value of 1 mΩ or more, or the Kelvin wiring predetermined portion is at least a part of the common Kelvin wiring and has a resistance value of 3 mΩ or more.

2. The switching module according to claim 1, wherein the plurality of switching elements are a number n (n is an integer of 2 or more) of switching elements, and the Kelvin wiring predetermined portion is the individual Kelvin wirings corresponding to a number n or n−1 of the switching elements.

3. The switching module according to claim 2, wherein the Kelvin wiring predetermined portion has a resistance value of 4 mΩ or more.

4. The switching module according to claim 2, wherein the Kelvin wiring predetermined portion has a resistance value of 10 mΩ or more.

5. The switching module according to claim 2, wherein the Kelvin wiring predetermined portion has a resistance value of 100 mΩ or more.

6. The switching module according to claim 1, wherein
the common Kelvin wiring extends so as to have both ends,
the individual Kelvin wirings corresponding to the plurality of switching elements are electrically connected to the common Kelvin wiring at an interval, and
the Kelvin wiring predetermined portion is a portion between a pair of points in the common Kelvin wiring, the pair of points to which a pair of the individual Kelvin wirings of a pair of the switching elements adjacent to each other are connected, and the portion corresponds to all of the switching elements.

7. The switching module according to claim 6, wherein the Kelvin wiring predetermined portion has a resistance value of 12 mΩ or more.

8. The switching module according to claim 6, wherein the Kelvin wiring predetermined portion has a resistance value of 30 mΩ or more.

9. The switching module according to claim 6, wherein the Kelvin wiring predetermined portion has a resistance value of 300 mΩ or more.

10. The switching module according to claim 1, wherein a sum of a resistance value of the Kelvin wiring predetermined portion and a resistance value of a control electrode resistor disposed on the control electrode wiring of the switching elements corresponding to the Kelvin wiring predetermined portion is a recommended gate resistance value of the switching elements.

11. The switching module according to claim 1, wherein the Kelvin wiring predetermined portion has a resistance value of 1 kΩ or less.

12. The switching module according to claim 1, wherein the control electrode wiring includes a common control electrode wiring having one end connected to a control wiring terminal and another end terminated, and individual control electrode wirings electrically connecting the common control electrode wiring to the control electrode of each of the plurality of switching elements.

13. The switching module according to claim 1, wherein the control electrode wiring includes a plurality of single control electrode wirings connected to a plurality of control wiring terminals, respectively, at one end and electrically connected to the control electrode of each of the plurality of switching elements at another end.

14. The switching module according to claim 1, wherein the switching elements are an insulated gate bipolar transistor (IGBT), a field effect transistor, or a bipolar transistor.
